(19) United States
(12) Patent Application Publication
(10) Pub. No.: US 2009/0096686 A1
(43) Pub. Date: Apr. 16, 2009

(54) AUTONOMOUS MOBILE WIRELESS ANTENNA SYSTEMS

(75) Inventors: Dragos Niculescu, Highland Park, NJ (US); Kyu-Han Kim, Ann Arbor, MI (US)

Correspondence Address: NEC LABORATORIES AMERICA, INC., 4 INDEPENDENCE WAY, Suite 200, PRINCETON, NJ, 08540, US

(73) Assignee: NEC LABORATORIES AMERICA, INC., Princeton, NJ (US)

(21) Appl. No.: 12/199,002

(22) Filed: Aug. 27, 2008

Related U.S. Application Data
(60) Provisional application No. 60/979,226, filed on Oct. 11, 2007.

(51) Int. Cl. H01Q 3/00; G01R 29/08

(52) U.S. Cl. 343/703; 343/757

(57) ABSTRACT

Systems and methods are disclosed for deploying one or more antennas by: mounting one or more antennas on a moving platform; searching a physical space and a signal space to locate a predetermined position for the one or more antennas to optimize data transmission; and actuating the moving platform to the predetermined position.

The present application claims priority to Provisional Application Ser. No. 60/979,226 filed Oct. 11, 2007, the content of which is incorporated by reference.

### BACKGROUND

The present invention relates to mobile wireless systems.

Many people use wireless networking to connect their computers at home. In the near future, wireless networking may become so widespread that people can access the Internet just about anywhere at any time, without using wires. Deployment and management costs become a significant burden in wireless systems from SOHO (small office and home office) to city-wide wireless cloud networks. This is mainly because of unreliable wireless links and changing operating environments. A method to address this variability is link adaptation, which adjusts transmission parameters to take advantage of the channel conditions through spectral, temporal and spatial multiplexing. The latter is based on the known fact that in many cases, wireless reception varies with location. On small scales (wavelength) this is caused by fading and multipath, and on larger scales it is caused by features in local geography. This diversity entails less predictability for mobile users, but also a chance to find better reception with slight position change. This is the basis for a number of techniques that exploit spatial diversity. The most basic of them is that of motorized satellite antennas which can be manually oriented toward a satellite.

On traditional access points the antenna is fixed with respect to the body of the transceiver. If there is an antenna array, all antenna elements have fixed positions. Many wireless cards nowadays come with connectors for two antennas so that the card can choose on the fly the one with better reception, usually without the support of the MAC layer. In a similar fashion, use of multiple cards implicitly exploits spatial diversity since their antennas are separate. MIMO technology exploits spatial diversity at the physical layer by using multiple antennas at the sender and receiver and is especially suited for highly scattered environments such as indoor environments. MIMO antenna arrays tune phase and amplitude of precisely spaced antenna elements to generate specific propagation lobes.

In general, wireless signal reception varies with location and is caused by multipath and fading phenomena. This phenomenon is more pronounced indoor, which is a highly scattered environment, but also happens outdoor. On small a scale, antenna locations differing by amounts on the order of the wavelength can have radically different performances. Over larger space scales indoors and outdoors, signal follows more predictable propagation rules, but still depends on the features of the environment. For example wireless reception of the same access point will be different in one room compared to another. Wireless systems often experience intermittent connectivity or varying network performance in time or space.

### SUMMARY

In a first aspect, a mobile system that transmits radio frequency signals over a signal space includes a platform to move over a physical space; one or more antennas mounted on the platform; and a controller coupled to the moving platform, the controller searching the physical space and the signal space and moving the platform to a position satisfying one or more criteria.

In another aspect, a mobile system includes a platform to move over a physical space; an access point mounted on the platform, the access point transmitting radio frequency signals over a signal space; one or more antennas coupled to the access point; and a controller coupled to the moving platform, the controller searching the physical space and the signal space and moving the platform to a position satisfying one or more criteria.

In yet another aspect, systems and methods are disclosed for deploying one or more antennas by: mounting one or more antennas on a moving platform; searching a physical space and a signal space to locate a predetermined position for the one or more antennas to optimize data transmission; and actuating the moving platform to the predetermined position.

Advantages of the preferred embodiments may include one or more of the following. The system is an inexpensive and compatible way to exploit spatial diversity. Low cost is achieved because the mobility can be provided by an inexpensive servo motor that controls spacing of the elements, and compatibility is achieved because the system is transparent to existing technologies at lower layers ((MIMO, beam forming) and upper layers (802.11, among others).

### BRIEF DESCRIPTION OF THE DRAWINGS

FIGS. 1A, 1B, and 1C show exemplary three autonomous wireless systems.

FIG. 1D shows an exemplary process deploying one or more antennas using the systems of FIGS. 1A-1C.

FIG. 2 shows an exemplary diagram of packet delivery ratio to a client.

FIG. 3A shows an exemplary software architecture of an autonomous wireless system.

FIG. 3B shows an exemplary monitoring protocol.

FIG. 4A shows a floor view with an exemplary position determination by an autonomous wireless robot.

FIG. 4B shows a picture of the autonomous wireless robot.

### DESCRIPTION

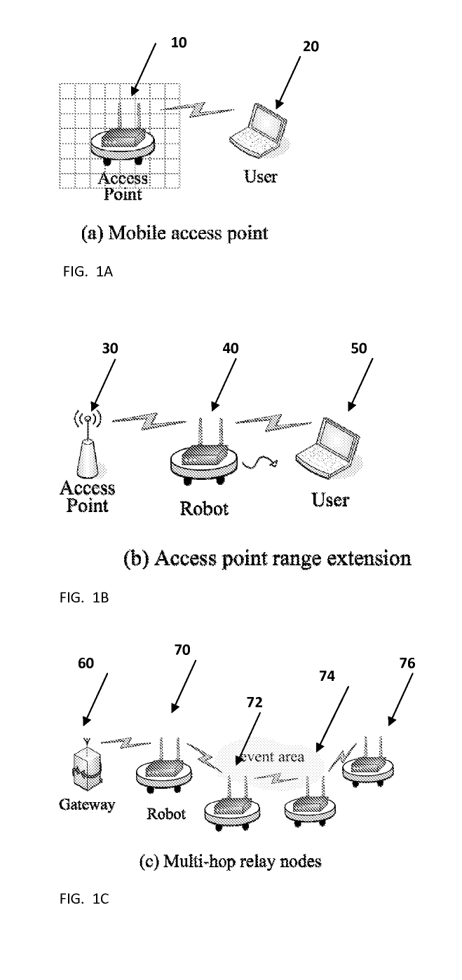

FIGS. 1A, 1B, and 1C show three autonomous wireless systems that move antenna position or direction to improve signal reception by exploiting the spatial diversity of radio signals. At a small scale, a MIMO rake could change the spacing between the elements to achieve better reception, better cancellation of interference, or control coupling between the elements. While this may not be feasible on a per packet basis, it is appropriate for point to point links that change only on large time intervals.

On a larger scale, a mobile relay node might change position by several meters in order to improve all links. An autonomous node might deploy itself so that it maximizes coverage for an instant mesh deployment. This mobility can bring further improvement in network performance of wireless systems, and also create additional potential applications of wireless systems with mobile antennas.

In FIG. 1A, a mobile access point (AP) 10 with mobile antennas and elements can move to optimize wireless reception for fixed links such as mobile nodes (MN) 20 that operate in dynamic environments. Elements can be moved with respect to each other so that a MIMO configuration can exploit patterns of interference or diversity combining from the new configuration. The entire system with antenna(s) can be moved to sample a point with potentially better reception or different polarization. For certain applications, the entire access point or base station can be moved to provide preferential service to a client, to improve a low performing link, to help in supporting extra load, or to provide extended coverage. The antenna attached to the AP 10 on ceilings can be moved to provide better network connectivity to mobile clients MN 20.

FIG. 1B shows another example where mobile relay WiFi routers 40 can autonomously find more beneficial locations and relay traffic to/from an AP 30 and one or more mobile clients 50. As shown in FIG. 1C, a group of robot-enabled mobile systems 70-76 can cooperate and form a multi-hop relay network with a base station 60 to provide instant wireless network connectivity for real-time applications such as emergency-response or disaster monitoring systems.

FIG. 1D shows an exemplary process deploying one or more antennas using the systems of FIGS. 1A-1C. In this process, one or more antennas are mounted on a moving platform (80). The system then searches a physical space and a signal space to locate a predetermined position for the one or more antennas to optimize data transmission (84); and the system then actuates motors on the moving platform to move the systems of FIGS. 1A-1C to the predetermined position (86).

Exploiting spatial diversity through physical mobility requires optimizing the system to the environment. To automate all phases of optimization, the system determines spatial characteristics of the underlying wireless links and autonomously adapts its configuration to the recognized characteristics. ‘Configuration’ here means either position of an antenna element, or position of the entire node.

In one embodiment, a characterization of spatial characteristics of wireless links is done. Even without mobility, stationary wireless links have time-varying characteristics due to co-channel interference, obstacles, or weather condition. Furthermore, small movement of antenna affects entire parameters of wireless links such as path-loss, shadowing, and multi-path effects. Whether these parameters are discrete or continuous in space is also an important factor in designing the system. For wireless links with stationary characteristics, the system has to effectively represent the spatial characteristics to make movement decisions.

In one embodiment, the mobile access point has AP antennas fixed with respect to its body while the entire AP is moving. After extracting spatial characteristics of wireless links, the system has to autonomously change its position or direction without human involvement. This is a closed loop process in that the system has to decide the next position based on previous measurement, and subsequently obtains measurements at the new location. This history-based approach allows the mobile AP system to reduce search space in finding optimal positions, but requires the mobile AP system to be location-aware in case it needs to backtrack.

The autonomous wireless systems of FIGS. 1A-1C determine spatial characteristics of wireless links for proper positioning. The autonomous wireless system can use simple parameters such as Signal-to-Noise Ratio (SNR) or packet-delivery ratio (PDR) which can be translated into packet-level link's bandwidth. These parameters represent the link status of one position, and thus need to be extended to spatial SNR (SSNR) and spatial PDR (SPDR). The system can also take into consideration the spatial scale for measurements. At small scales, the system can achieve significant performance benefits with a movement of a few centimeters when at the edges of coverage area. At larger scales, the system might need to move away more than several meters (for example away from a jamming area). In addition, depending on the size of space, spatial characteristics can be captured.

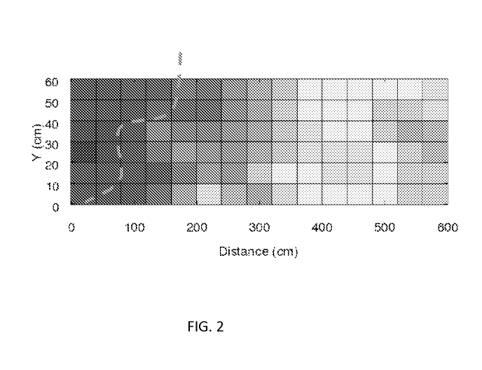

In FIG. 2, packet delivery ratio to a client is systematically sampled every 10 cm showing potential benefits that can be achieved even with small scale movement. The spatial characteristics can be highly correlated with features in the space. These characteristics can be correlated with obstacle, distance, or interference source. Wireless systems should be able to take advantage of these correlations to characterize spatial wireless link-quality.

To optimize locations of wireless systems, these spatial characteristics have to be stored and used as history. Because spatial characteristics information needs to be associated with time and location, the system needs location information in a fine-grained manner. Existing GPS service is not accurate in indoor environments such as buildings, or capable of supporting accuracy of a few centimeters. To exploit spatial diversity, spatial measurement and autonomous relocation techniques can be used.

In one implementation of a mobile AP (RoverAP), the system analyzes the underlying wireless environments and adapts to the environments accordingly. These two tasks closely interact with each other and can be realized based on following four design principles:

P.1 Real-Time Measurement:

The RoverAP system has to meet given time-constraints with measurement accuracy. To this end, the system has to proactively measure the quality of links from itself to neighboring nodes. In addition, because the system needs to measure at different discrete positions, each measurement has to be done within fixed time period.

P.2 Spatial Correlation Profiling:

Based on discrete measurements in a certain area, RoverAP needs to profile correlation among measurement points. This spatial correlation is then used for determining next directions or areas to be measured.

P.3 Adaptive Measurements:

The frequency and areas of measurement can be adaptively determined, depending on their spatial characteristics. Based on measured results in one point, the system can change parameters for the next interval of measurements. In addition to the interval, the system also adjusts size of the measurement areas depending on variability of measurements.

P.4 Measurement-Aware Navigation:

At each measurement, a wireless system records both measurements and their measure-point (location) to a spatial correlation profile. In addition to the measurement accuracy, location accuracy is also important. To avoid dependency from other services such as expensive indoor positioning systems, the system provides its own location detection and correction capability.

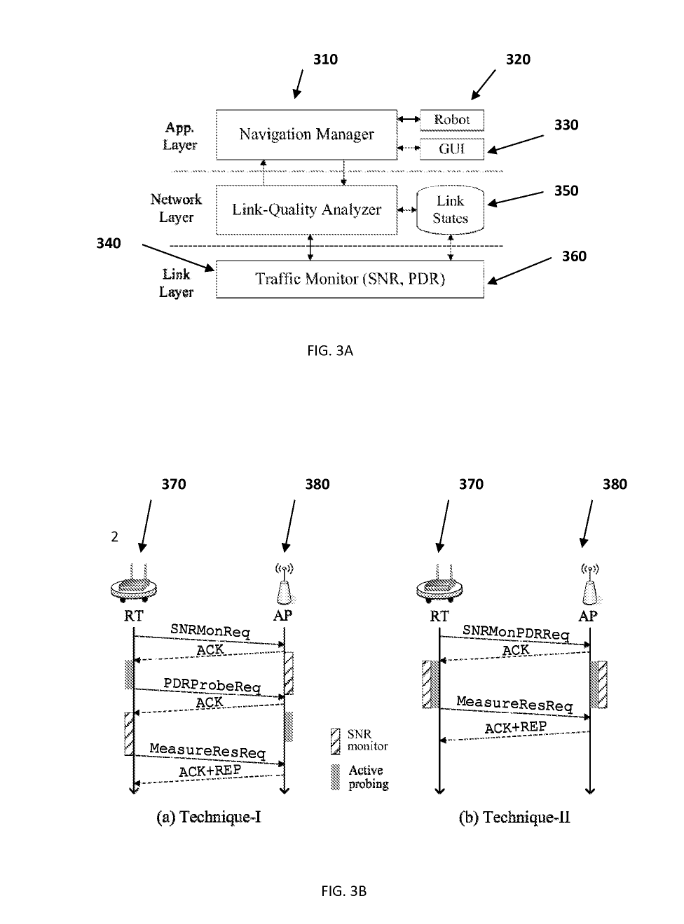

Following the above design principles, FIG. 3A shows the software architecture of the RoverAP system. The RoverAP system is composed of a link-quality analyzer 340 and a navigation manager 310. Both components are implemented across application, network and link layers on top of a Linux IEEE 802.1 I-based AP. In FIG. 3A, a navigation manager 310 resides at the application layer and communicates with a robot 320 to provide AP mobility. The navigation manager 310 also provides a graphical user interface 330 to allow users to manage and control the RoverAP system.

Next, the link-quality analyzer 340 is discussed. The system assumes that wireless clients and APs are mostly static during service, so the RoverAP system measures the quality of wireless links at several points before settling for a preferred location. For example a link to a laptop is worth optimizing, as the link may be used for minutes of hours, whereas a link to a mobile phone incurs too high variability. The role of link-quality analyzer (LA) is to i) measure wireless link-quality at one point and ii) derive spatial characteristics.

1) Measuring Link-Quality at a Measure-Point:
To accurately measure wireless link-quality at one point: (i) the measurement at each point has to be done within a few seconds with a certain level of accuracy; (ii) the measurement has to be done per link in each direction to account for asymmetry; and (iii) the measurement has to be adaptive in deciding a measurement point, depending on its channel states and its mobility. First, to facilitate a measurement with high accuracy, a mobile router uses both active probing and passive monitoring. The RoverAP system uses tmicast probing packets from itself and requires passive monitoring in a receiver node. By doing so, the system can measure both packet-delivery ratio and SNR for each directed link. Next, because wireless links often show asymmetric link-quality, the measurement can be done unidirectionally so that the Rover AP system can properly characterize the asymmetry. Once it positions itself, the RoverAP system initiates active probing to a destination node. At the initiation stage, the system sends a request for the destination to monitor SNR of active probing packet. During active probing, the RoverAP also monitors transmission results of probing packets based on traffic monitoring results. After finishing one direction, the RoverAP system sends an active probing request to the destination and prepares for SNR monitoring. This process is summarized in FIG. 3B. Finally, the system derives a channel state index to decide its frequency of measurements. If channel states change drastically in a short period, a router needs to spend more time on measurements. For example, if the system is close to an access point or neighboring nodes, link-quality overall shows high throughput. On the other hand, if the system comes across the boundary of wireless coverage, it requires fine-grained measurements to detect the boundary.

2) Deriving Spatial Link-Quality Over an Area:
After measuring wireless link-quality at measure points, the RoverAP system derives spatial link-quality by applying an averaging filter. Over a continuous area (rectangular) the RoverAP system averages four values of link-qualities to represent spatial characteristics of that area. Using an average filter helps in smoothing out noisy link-quality measurements. In addition, the RoverAP system also measures link-quality three times at random directions at each measure-point to tackle high frequency noise in the link-quality measurement.

Turning now to the navigation management for RoverAP, the RoverAP navigation manager 310 navigates a given area to find (sub-)optimal place where wireless links can meet QoS demands. If the link geometry is stable in the long term, the system can perform an exhaustive search periodically and choose the position that gives the best signal. However, exhaustive search over the area can require extensive time and resource usage (e.g., an area of 1 m×1 m with 10 cm scale requires measurements at 100 measure-points). For changing links such as those to mobile users, this strategy would take too long. Instead, RoverAP can use correlation of spatial characteristics of local areas, and use interpolation or extrapolation techniques to reduce search space. In essence the system performs a greedy optimization using the gradient method (Newton) to find a location with a reasonable signal quality in a short time.

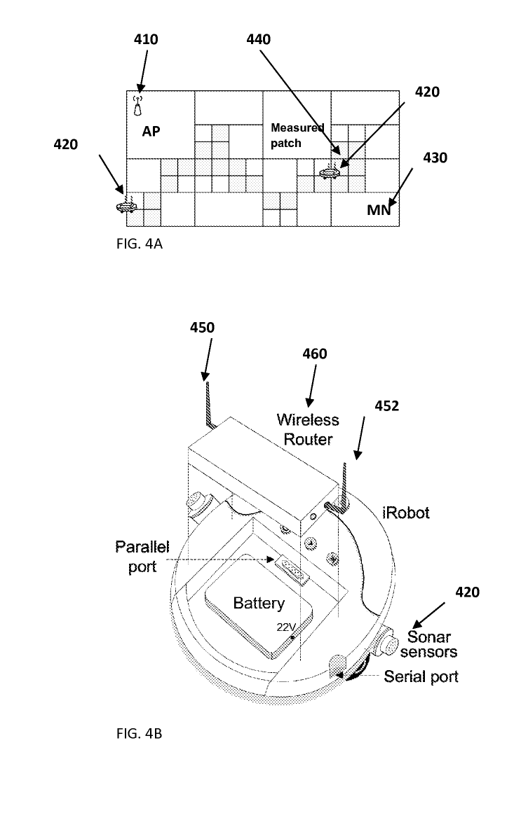

In FIG. 4A, the RoverAP uses a greedy optimization to find a position as far away as possible from the access point, while still maintaining a reasonable signal quality. In FIG. 4A, the AP 410 is positioned diagonally opposite to a mobile node 430. The area to be served by the AP 410 is divided into an array of measured patches 440. A RoverAP 420 enters the space at a begin patch, and after optimization, moves to an end patch. The purpose here is to maximize the potential coverage by acting as a relay for the access point that has access to the wired network.

As explained above, spatial correlation exists over a certain area. The objective of the navigation is to find a patch that provides wireless link quality of given QoS demands. The RoverAP can decide the optimality of the position by calculating the correlation of link-quality. For large scale navigation such as an entire floor of a building, using a base as an absolute position is not feasible due to its short range of coverage. Instead, the robot uses natural landmarks to identify its location. This landmark-based navigation consists of a two-step procedure. Initially, the robot learns of landmarks, which can be done using manual training. This is quite labor intensive, so an automated procedure, such as SLAM is more appropriate to gather the landmarks in a large building. Landmark training and use can be performed using a variety of technologies including sonar, laser, and image analysis. RoverAP uses side mounted sonars that detect specular landmarks such as door frames, walls, furniture, among others.

The system can also perform dead-reckoning with error correction. The simplest way to locate the robot is to use simple trajectory models such as lines, rectangles, and spirals. When navigating, the robot keeps track of its current position, but the errors in odometry keep accumulating as the robot travels. One challenge is how to deal with the accumulation of the odometry errors, especially in the angle. For example, if the robot rotates 181 degree upon a 180 rotation request, its trajectory would deviate from its expected line by a large amount, even if the original angle error was small. These problems are less critical for the small scale navigation required for greedy optimization since the actual global position is not critical. Here the robot only needs to backtrack a limited space to use a location visited in the recent past, as opposed to traveling across the building.

In one embodiment, the RoverAP 420 is implemented in a Linux-based software access point mounted on a robot as shown in FIG. 4B. The access point has a controller with RAM/ROM and wireless transceivers such as 802.11 transceivers. In addition to access point functions, the controller is also programmed to control the iRobot. The iRobot is used for an underlying base of RoverAP to provide a robust, low cost indoor robotics platform. The iRobot has a battery independence of four hours of continuous driving which is matched by the capacity of the access point battery. A multi-radio router 460 is mounted on top of the robot with omni-directional antennas 450 and 452. Two Maxbotix sonars are provided for measuring distance from the robot to obstacles and landmarks. The Maxbotix sonar has a range of 6 m is used for both landmark collection and navigation. Using the above hardware, the system has been implemented in a Linux environment which allows access to the packet processing code in the kernel.

As shown in FIG. 2A, the mobile antenna optimization algorithms have been implemented for the Linux kernel using netfilter and MADWiFi device driver. The mobility manager 310 has been implemented at the application layer in user space. The communication interface between the mobility manager and the modules relies on simple socket programming, and the interface between the link-quality monitor and the traffic tracer simply exploits ioctl functionality in Linux.

In another implementation, the RoverAP could access the wired network while charging using Ethernet over power line technology. In this way, RoverAP behaves as a regular access point when its mobile capabilities are not needed.

The autonomous wireless systems can recognize spatial characteristics of wireless links and relocate themselves. The RoverAP system enables wireless systems to improve underlying network performance and reduce management cost via robot-based mobility.

In yet another embodiment, the system can form malleable networks where each nodes can collaboratively reconfigure the network to support new conditions. In addition, joint optimization of mobility can be done with other spatial diversity technologies (e.g. MIMO, beam-forming, among others).

The RoverAP 420 provides mobile antennas and elements as a way to optimize wireless reception for fixed links that operate in dynamic environments. Elements can be moved with respect to each other so that a MIMO configuration can exploit patterns of interference or diversity combining from the new configuration. The entire antenna can be moved to sample a point with potentially better reception or different polarization. For certain applications, the entire access point or base station can be moved to provide preferential service to a client, to improve a low performing link, to help in supporting extra load, or to provide extended coverage.

The RoverAP 420 of FIG. 4B performs a search in the physical space and in signal space and finds a position that satisfies multiple criteria. In the example of FIG. 4A, the robot deploys itself as far as possible from the access point while still maintaining reasonable strength of the signal.

Since signal varies with space, exploring a new position brings benefits to the signal quality. In MIMO or antenna arrays these element are fixed, and their achievable optimization space is limited to whatever signal they can harvest at their deployed positions. A mobile element antenna searches through all the available positions to choose the optimal one that optimizes the channel to the receiver. A mobile relay need not be deployed with a precise radio survey, as it can optimize its own position to give better coverage, or it can react to nomadic user patterns.

The mobile element/antenna and mobile AP can be combined in the same product, can be used with legacy products, or can be used together with other spatial diversity schemes such as MIMO or beam-forming. For example, a legacy MIMO antenna can be used on a mobile AP; an antenna array can be optimized by moving the entire assembly, or by changing its geometry, or both.

The invention may be implemented in hardware, firmware or software, or a combination of the three. Preferably the invention is implemented in a computer program executed on a programmable computer having a processor, a data storage system, volatile and non-volatile memory and/or storage elements, at least one input device and at least one output device.

Each computer program is tangibly stored in a machine-readable storage media or device (e.g., program memory or magnetic disk) readable by a general or special purpose programmable computer, for configuring and controlling operation of a computer when the storage media or device is read by the computer to perform the procedures described herein. The inventive system may also be considered to be embodied in a computer-readable storage medium, configured with a computer program, where the storage medium so configured causes a computer to operate in a specific and predefined manner to perform the functions described herein.

The invention has been described herein in considerable detail in order to comply with the patent Statutes and to provide those skilled in the art with the information needed to apply the novel principles and to construct and use such specialized components as are required. However, it is to be understood that the invention can be carried out by specifically different equipment and devices, and that various modifications, both as to the equipment details and operating procedures, can be accomplished without departing from the scope of the invention itself.

What is claimed is:

1. A mobile system to communicate radio frequency signals over a signal space, comprising:
a. a platform to move over a physical space;
b. one or more antennas mounted on the platform; and
c. a controller coupled to the moving platform, the controller searching the physical space and the signal space and moving the platform to a position satisfying one or more criteria.

2. The system of claim 1, wherein the controller analyzes the underlying wireless environments and moves the platform to the environments accordingly.

3. The system of claim 1, wherein the controller measures link quality to neighboring nodes at different discrete positions and wherein each measurement is performed within a predetermined time period.

4. The system of claim 1, wherein the controller performs spatial correlation among measurements and determining next directions or areas to be measured.

5. The system of claim 1, wherein the controller adaptively determines measurement frequency and areas of measurement based on spatial characteristics.

6. The system of claim 1, wherein the controller performs location detection and position correction using active probing and passive monitoring.

7. The system of claim 1, wherein the controller measures packet-delivery ratio and signal to noise ratio (SNR) for each directed link.

8. The system of claim 1, wherein the controller measures RF signals unidirectionally to characterize an asymmetric link-quality.

9. The system of claim 1, wherein the controller derives a channel state index to decide its frequency of measurements.

10. The system of claim 1, wherein the controller determines the position optimality calculating the correlation of link-quality.

11. The system of claim 1, wherein the controller detects landmarks to identify a location.

12. A mobile system, comprising:
a. a platform to move over a physical space;
b. an access point mounted on the platform, the access point communicating radio frequency signals over a signal space;
c. one or more antennas coupled to the access point; and
d. a controller coupled to the moving platform, the controller searching the physical space and the signal space and moving the platform to a position satisfying one or more criteria.

13. The system of claim 1, wherein the controller measures link quality to neighboring nodes at different discrete positions and wherein each measurement is performed within a predetermined time period.

14. The system of claim 1, wherein the controller performs spatial correlation among measurements and determining next directions or areas to be measured.

15. The system of claim 1, wherein the controller adaptively determines measurement frequency and areas of measurement based on spatial characteristics.

16. The system of claim 1, wherein the controller performs location detection and position correction using active probing and passive monitoring.

17. The system of claim 16, wherein the controller measures packet-delivery ratio and signal to noise ratio (SNR) for each directed link; measures RF signals unidirectionally to characterize an asymmetric link-quality; and derives a channel state index to decide its frequency of measurements.

18. The system of claim 1, wherein the controller determines the position optimality calculating the correlation of link-quality.

19. The system of claim 1, wherein the controller detects landmarks to identify a location.

20. A method to deploy one or more antennas, comprising:
a. mounting one or more antennas on a moving platform;
b. searching a physical space and a signal space to locate a predetermined position for the one or more antennas to optimize data transmission; and
c. actuating the moving platform to the predetermined position.
